(19) United States
(12) Patent Application Publication
(10) Pub. No.: US 2011/0033618 A1
(43) Pub. Date: Feb. 10, 2011

(54) GAS SUPPLY SYSTEM AND METHOD FOR PROVIDING A GASEOS DEPOSITION MEDIUM

(76) Inventors: Oliver Nöll, Schwalmtal (DE); Tobias Kleyer, Herdecke (DE)

Correspondence Address: Ballard Spahr LLP, SUITE 1000, 999 PEACHTREE STREET, ATLANTA, GA, 30309-3915, US

(21) Appl. No.: 12/598,470

(22) PCT Filed: Apr. 30, 2008
(86) PCT No.: PCT/EP08/55385

§ 371 Date: Oct. 1, 2010

(30) Foreign Application Priority Data
May 2, 2007 (DE) 10 2007 020 852.0

(51) Int. Cl. C23C 16/44; C23C 16/46

(52) U.S. Cl. 427/248.1; 118/724; 118/723 R

(57) ABSTRACT

A gas supply system for a gas phase deposition reaction chamber, in particular a CVD gas phase deposition reaction chamber or a PECVD gas phase deposition reaction chamber, comprises a gas supply device which has at least one heating element for heating a deposition medium and transferring the deposition medium into the gaseous phase. Furthermore, the gas supply system comprises a gas feeding device for transporting the gaseous deposition medium from the gas supply device to the gas phase deposition reaction chamber, wherein the gas feeding device comprises a sealing element at the transition to the gas phase deposition reaction chamber. As a result, it is possible to provide a gas supply system for a gas phase deposition reaction chamber allowing a homogeneous feeding of even deposition media which are not present in gaseous form at room temperature into the reaction chamber.

The invention relates to a gas supply system for a gas phase deposition reaction chamber.

Gas phase deposition methods are essentially divided into physical gas phase deposition methods (PVD methods) and chemical gas phase deposition methods (CVD methods).

CVD (chemical vapor deposition) methods are coating processes in which a solid, very thin layer is deposited on a substrate surface out of the gas phase through chemical reaction in a gas phase deposition reaction chamber.

In contrast with PVD (physical vapor deposition) methods, in which a solid material is transformed into the gas phase through vaporization or atomization, the CVD methods require easily volatile educts present in their gaseous state that are brought to a reaction through a supply of energy in a reaction chamber.

The various CVD methods are differentiated according to the type of activation. The supply of energy may occur either thermally or by means of plasma, as, for example, in the PECVD method (plasma enhanced chemical vapor deposition).

In the PECVD method, a deposition of thin layers occurs through chemical reaction as in the CVD method; however, in the PECVD method, the coating process is additionally supported by plasma. To this end, a strong electrical field is created in the reaction chamber between the substrate to be coated and a counter electrode by which plasma is ignited. The plasma causes a break-up of the bonds of a gaseous deposition medium also called reaction gas and breaks down into the individual radicals that settle on the substrate where they effect the chemical deposition reaction. Because of the plasma, a higher deposition rate can be achieved in the PECVD method in conjunction with a lower deposition temperature than with the CVD method.

As a basic principle, it is a prerequisite for the deposition of a certain material that it can be rendered available in a gaseous aggregate state. In this way, the deposition media to be used are already in a gaseous phase and can thus be easily guided into the reaction chamber from the gas supply system located outside of the reaction chamber and fed to the plasma.

In the following, deposition media present in a gaseous aggregate state at room temperature will be called reaction gases.

However, the selection of substances that are present in a gaseous state at room temperature is quite limited. Carbon-containing acetylene (C₂H₂) or methane gases are possible reaction gases for the production of a carbon-containing coating such as, for example, DLC (diamond-like carbon). Gaseous tetramethylsilane (TMS), for example, is a possibility for the production of a silicate coating.

However, there is considerable demand for coatings that are not, or not exclusively, based on carbon and/or silicates. In this context, for example, semiconductor metals would have to be mentioned that display special properties when deposited on a carrier material in thin layers. As a rule, no deposition materials that are gaseous at room temperature are available for these materials, i.e. no reaction gases containing and/or providing the respective material.

Therefore, it is the objective of the invention to provide a gas supply system for a gas phase deposition reaction chamber as well as a method that is suitable to make those materials available for gas phase deposition for which no reaction gases are available that are gaseous at room temperature.

In accordance with the invention, this objective is met by a gas supply system with the characteristics of Claim 1 as well as by a method for the provision of a gaseous deposition medium with the characteristics of Claim 10. Advantageous embodiments of the invention are indicated in the subclaims. In this context it must be observed that any value ranges that are limited by numeric values are always to be understood with the inclusion of the numeric values mentioned.

Accordingly, a gas supply system is provided for a gas phase deposition reaction chamber that is equipped with a gas supply device, with the gas supply device having at least one heating element to heat a deposition medium that is solid or liquid at room temperature and to convert the deposition medium into the gas phase. Moreover, the gas supply system has a gas feed device for transporting the deposition medium converted into the gas phase from the gas supply device into the gas phase deposition reaction chamber.

For the sake of simplicity, the term “deposition medium that is solid or liquid at room temperature” will be replaced by the term “deposition medium”. Separate therefrom, as mentioned above, the term “deposition medium that is gaseous at room temperature” will be replaced by the term “reaction gas”.

In the gas supply device in accordance with the invention which is arranged outside of the gas phase deposition reaction chamber, hereinafter “reaction chamber”, a deposition medium that is solid or liquid at room temperature is heated to a point where it can be converted into the gas phase. Thus, it is, so to speak, vaporized (transition from liquid to gaseous), sublimated (transition from solid to gaseous) or, initially melted (transition from solid to liquid) and then vaporized.

To generate the heat required for that purpose, the gas supply device has at least one heating element, preferably several heating elements for quicker heating, which may preferably be designed as infinitely variable heating coils.

In this context it is particularly advantageous to provide that one heating element each is installed in the vaporizing unit as well as in the feed line and in the valve.

Following the conversion into the gaseous state, the deposition medium is transported from the gas supply device into the gas phase deposition reaction chamber via the gas feed device in accordance with the invention. To that end, the gas feed device is equipped with a tube-shaped line that connects the gas supply device with the reaction chamber and preferably extends all the way into the interior space of the reaction chamber. During the transport of the gaseous deposition medium from the gas supply device all the way into the reaction chamber it is of importance that the deposition medium be kept at the vaporization temperature of the respective deposition medium up to the point in time when it is in the reaction chamber so that the deposition medium can not go from the gaseous state back to the liquid or solid state due to a loss of heat during transport.

Thus, with the combination of characteristics of the invention it is made possible that deposition media that are present in solid or liquid state at room temperature are first vaporized or sublimated before being fed into the reaction chamber. When using deposition media that must be converted to the gaseous state before entering the reaction chamber, the problem lies in the transport from the area outside of the reaction chamber where the deposition medium is vaporized all the way into the reaction chamber which would cause the deposition medium to go back into its liquid or solid phase so that a homogeneous feed would no longer be possible and that moreover the feed lines may become clogged by any solidified deposition medium. In particular in the case of coating processes in which the reaction chamber is not heated, the transport of the deposition media that are not present in the gaseous state at room temperature is particularly problematic during the transition to the reaction chamber. This problem is solved in accordance with the invention through the heating element that is provided.

It is preferable in this context that the gas phase deposition reaction chamber involves a PECVD (plasma enhanced vapor deposition) chamber. Here, plasma is ignited in the reaction chamber with the aid of which the feed gases are ionized and accelerated.

In contrast with the CVD method mentioned above earlier, the temperature in the reaction chamber remains moderate in the PECVD method and usually does not exceed 250° C., preferably 120° C. For this reason, this arrangement requires a precise temperature management since at the relatively low temperatures in such a system—unlike, for example, in CVD systems with very high temperatures of <500° C.—there would otherwise be the danger of condensation of the deposition medium which, on the one hand, would negatively affect the coating process and which, on the other hand, could damage the feed equipment (valves, ducts, etc.).

Preferably, the gas feed device is equipped with a sealing element at the transition point to the gas phase deposition reaction chamber. It will prevent a heat transfer between the gas supply device or, respectively, the tube-shaped line and the reaction chamber. The sealing element is preferably arranged in the transition area between the gas supply device or, respectively, the tube-shaped line and the reaction chamber above the exterior circumferential surface of the gas supply device or, respectively, the tube-shaped line, preferably in force-fitting fashion. In the area of the opening of the reaction chamber through which the tube-shaped line is guided into the interior space of the reaction chamber, the sealing element is arranged in such a way that it will bring about a pneumatic and thermal seal between the exterior circumferential surface of the gas supply device or, respectively, the tube-shaped line and the wall of the reaction chamber.

Moreover, a particularly preferred provision is the fact that the gas supply device and the gas feed device are designed as a continually tempered and/or thermally insulated continuum. In this manner it will be prevented that during the transport no cooling off of the vaporized or, respectively, sublimated deposition medium can take place, if at all possible.¹ For example, it is provided in this respect that the tube-shaped line is made of an insulating material and/or that it can be heated along the line. Translator's note: I do not believe that this is what the author intended to say.

In particular for the coating of substrates that can hardly be heated during the coating process due to their structure such as, for example, PP, PC or ABS, the reaction chamber is not or only marginally heated for the coating process so that it will be possible that the gaseous deposition medium, upon entry in the reaction chamber, has a higher temperature than the temperature of the reaction chamber itself. In this respect, the sealing element advantageously prevents a heat transfer so that, on the one hand, the reaction chamber is not heated by the gas supply device in the transition area and that, on the other hand, that the lower temperature of the reaction chamber is not transferred to the tube-shaped line and thus to the gaseous deposition medium which would cause a detrimental lowering of the temperature of the heated gaseous deposition medium. Consequently, the sealing element achieves a thermal and airtight sealing effect.

With the solution in accordance with the invention it is therefore possible to transform a deposition medium that is liquid or solid at room temperature and whose vaporization temperature lies above room temperature into a gaseous state outside of the reaction chamber and to feed it via a gas supply device into the reaction chamber in its gaseous state without it being possible that a heat loss in the deposition medium may occur during the transport of the gaseous deposition medium. Preferably, the deposition medium is kept at an essentially constant temperature from its transformation into the gaseous state in the gas supply device all the way into the reaction chamber. This will also make a homogeneous feed of deposition media possible whose vaporization temperature lies above room temperature. In addition, the gas supply system in accordance with the invention considerably increases the effectiveness.

In this context, it may be provided that the gas supply device is equipped with its own low-pressure system to generate a negative pressure. However, it may also be provided that a negative pressure is created in the gas supply device via the gas feed device that corresponds to the negative pressure in the reaction chamber.

For some deposition media, one proceeds in such a way that—with an open valve—a negative pressure is created in the gas supply device via the gas feed device before the medium is heated. After a defined negative pressure has been generated, the valve is closed. Since due to the lowered pressure the vapor pressure of the deposition medium is increased, causing the evaporating or sublimating temperature to drop, the deposition medium needs to be heated to a relatively lower temperature.

Substances with a low boiling point or sublimation point can be transformed into the gaseous phase without prior evacuation of the gas supply device solely through heating with a closed valve under normal pressure and then be fed in their gaseous state into the evacuated process chamber via valves in a defined manner.

Preferably, it is provided that titanium, silicon, gallium, indium, molybdenum, copper, selenium, cadmium or zinc are to be applied on a material. These materials have, among other things, semiconductor properties and, applied on a carrier material in thin layers, they will display special properties.

In most cases, these materials can not be made available in the form of a deposition medium that is gaseous at room temperature (“reaction gas”).

As deposition media, the media listed in the following table are possible candidates, among others:

TABLE 1

| | Deposition Medium | |
|---|---|---|
| Material | (Example) | Aggregate State at Room Temperature |
| Ti | TiO₂ | solid |
| Ti | Ti[OCH(CH₃)₂]₄ | solid |
| Si | O[Si(CH₃)₃]₂ | liquid |
| Ga | C₁₅H₂₁GaO₆ | solid |
| In | C₁₅H₂₁InO₆ | solid |
| Mo | C₆O₆Mo | solid |
| Cu | C₁₀H₂CuF₁₂O₄ | solid |
| Cu | C₁₀H₁₄CuO₄ | solid |
| Se | C₆H₅SeH | solid |
| Cd | (Cd(SC(S)N(C₂H₅)₂]₄) | solid |
| Zn | Zn(C₅H₇O₂)₂ | solid |
| Sn | C₈H₂₀Sn | liquid |

However, as a matter of principle, possible candidates are all other compounds that are solid or liquid at room temperature and that contain one or several of the materials named above and that can be transformed into the gaseous phase under the aforementioned conditions. Preferably, the deposition materials to be used involve metal-organic compounds. Such compounds are characterized by the fact that one or several organic residues or, respectively, compounds are directly bonded to a metal atom.

In this context, it is a prerequisite that the respective deposition medium be present in a solid or liquid aggregate state at room temperature and that it can be transformed into the vapor phase at a temperature of maximally 1,500° C., preferably 1,000° C. (if necessary, under negative pressure) and thus can be fed into the subsequent PECVD process.

From the literature, many compounds are known that are solid or liquid at room temperature and that contain one or several of the abovementioned materials. With regard to titanium isopropoxide, for example, it is known that the boiling point at 1,333 Pa (10 mmHg) is 218° C.

For many of the other materials, the boiling and/or sublimation points, in particular under negative pressure conditions, are not known. Therefore, in elaborate preliminary investigations, the inventors identified compounds that appear to be suitable based on the literature, and subsequently tested them on their usability.

Moreover, various mixtures of these deposition media are possible which are then jointly transformed into the gas phase in one vaporizer or in several vaporizers arranged parallel or connected in series.

As a matter of principle, the method is also suitable for the deposition of additional materials other than those mentioned in the list above. Possible candidates as materials are, for example, the elements Al, Sb, As, Ba, Be, Bi, B, Ge, Au, Hf, Tr, Fe, Pb, Li, Mg, Mn, Hg, Ni, Nb, Pd, Pt, K, Ce, Dy, Er, Eu, Gd, Ho, La, Lu, Nd, Pr, Sm, Sc, Tb, Tm, Yb, Y, Re, Rh, Rb, Ru, Ag, Sn, Na, Zr, Te and Tl.

Preferred organometallic deposition media for these materials that need to meet the abovementioned conditions with regard to aggregate state and sublimation or, respectively, boiling point can be found in the catalog “Metal Organics for Material Polymer Technology” of the firm of ABCR GmbH, 76151 Karlsruhe, whose contents is to be added in its complete scope to the disclosure contents of this application.

In accordance with a particularly preferred embodiment, a valve (34) controlling the feed of the gaseous deposition medium (20) is provided between the gas supply device and the gas phase deposition reaction chamber. In this context, the valve is arranged along the tube-shaped line, preferably in the segment shortly before the point where the deposition medium is fed into the reaction chamber. The valve is preferably designed as a needle valve and, in an additional preferred embodiment, is equipped with one or several heating elements.

Also, it may be provided that a valve is arranged between the gas supply device and the gas phase deposition reaction chamber to control the pressure conditions between the two devices.

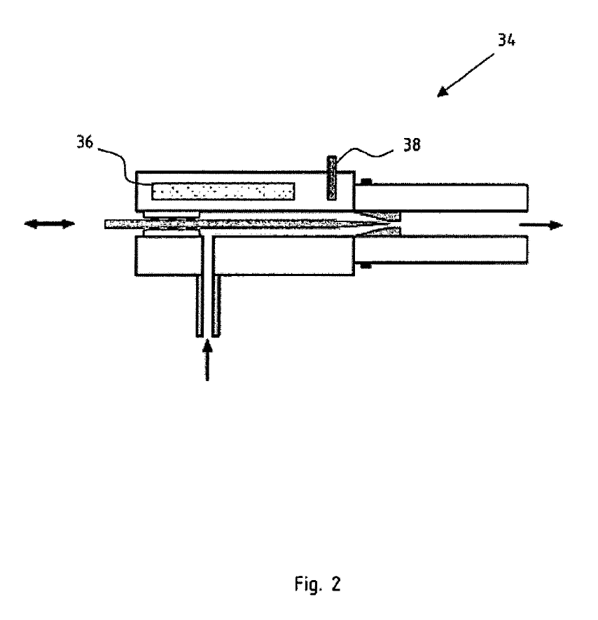

The aforementioned needle valve is shown, for example, in FIG. 2 and has considerable advantages as compared to conventionally used devices for metered additions such as, for example, mass flow controllers (MFC) or [missing part]. For example, mass flow controllers are incapable of assuring constant temperatures across the entire gas course covered by them. Experiments conducted by the applicants have shown that a gas guided and controlled through a mass flow controller is subject to temperature fluctuations of up to ±2° C. and more. This may lead to condensation of deposition medium, in particular at relatively low reaction temperatures that are present, for example, in a PECVD chamber, thereby leading to the aforementioned disadvantages. In particular, there is the danger that such a mass flow controller will then clog up and become inoperative.

In addition, the aforementioned needle valve may be designed as extremely heat-resistant so that it will survive temperatures of up to 600° C., in contrast with a MFC that will not survive these temperatures.

This may be advantageous in the case of deposition media that need to be heated to very high temperatures in the gas supply system in accordance with the invention in order to transition into the gas phase.

Due to the heat resistance of the needle valve, such media are able to pass through the valve at the aforementioned temperature and do not cool until downstream of the valve, i.e. in the reaction chamber, where preferably a high vacuum prevails and there is no longer any danger of condensation.

The aforementioned needle valve is therefore particularly advantageous when the gas phase deposition reaction chamber involves a PECVD chamber in which—in contrast with the abovementioned CVD method—the temperature in the reaction chamber remains moderate (see above) and the deposition medium, if necessary, needs to be heated to very high temperatures. The needle valve prevents the aforementioned temperature fluctuations and thus makes a precise temperature management of the deposition medium transformed into the gaseous state possible; in addition to that, it is capable—in contrast with an MFC—of surviving the high temperatures of the deposition medium that may be necessary under certain circumstances.

An added advantage is the fact that in the case of said needle valve, the passage opening, for example the valve bore hole, can be adapted to the respective deposition medium to be used. For example, for deposition media with relatively high molecular or, respectively, atomic weights, a larger passage opening may be selected than for deposition media with relatively low molecular or, respectively, atomic weights.

The following table presents examples of weight and size relationships:

| | | | Passage |
|---|---|---|---|
| | Atomic | Deposition Medium | Opening |
| Material | Weight | (Example) | [mm] |
| Titanium (Ti) | 47.86 | titanium isopropoxide | 0.02 |
| Copper (Cu) | 63.54 | copper hexafluoracetylacetonate | 0.025 |
| Tin (Sn) | 118.71 | tetraethyl tin | 0.15 |

In this context, it is preferable to adjust the valve to the same temperature as the gaseous deposition medium flowing through, in particular to the vaporization temperature of the deposition medium so that the deposition medium can not cool down when streaming through the valve. The volume flow of the deposition medium streaming into the reaction chamber is controlled with the aid of the valve so that a precise dosing of the deposition medium streaming into the reaction chamber is made possible for an optimal coating. As a rule, the measuring unit in this case is the magnitude “sccm”. This short form stands for “standard cubic centimeter per minute” and represents a standardized volume flow. Independent of pressure and temperature, this standard registers a defined flowing gas amount (particle number) per unit of time. A sccm is a gas volume of V=1 cm³=1 ml under standard conditions (T=20° C. and p=1,013.25 hPa).

In this constellation, the aforementioned valve has a double role since, on the one hand, it serves to control the pressure conditions between the reaction chamber and gas supply device and, on the other hand, functions as a control unit for a defined gas flow. In the practical implementation, one valve may be used for both tasks, as well as a variant with two different valves for the respective purposes.

For example, a dosable valve is not required in every case for controlling the pressure conditions between the reaction chamber and the gas supply device. Here, for example, a simple spigot could be of use. The control of a defined gas flow, on the other hand, requires an extremely precisely dosable valve, if necessary together with a control unit.

As a matter of principle, gas flow values of between 10 sccm and 1,000 sccm are usable for all gases.

Preferably, the sealing element involves an element, preferably a ring, made of PTFE (polytetrafluoroethylene). The PTFE ring preferably abuts the exterior circumferential surface of the tube-shaped line in force-fitting and airtight fashion.

PTFE has great mechanical and thermal resilience as well as great chemical resistance. This is augmented by a low heat conduction coefficient.

In principle, however, other materials with similar properties with regard to mechanical and thermal resilience as well as, if necessary, chemical resistance and heat conducting coefficient are suitable as well.

But here, other possible candidates are, for example, high-melting thermoplastics. Likewise, ceramic and glass materials may be considered. The latter may be made dense through the application of appropriate grindings.

Furthermore, in accordance with a preferred embodiment, the gas supply device is equipped with a first container and a second container arranged in the first container, with the heating element and a transfer medium for the transfer of the heat provided by the heating element to the second container being provided in the first container and the deposition medium being provided in the second container. In this context, preferably only one deposition medium will be located in the second container at any time to prevent any undesired mutual influences of different deposition media on each other. In accordance with the invention, the exterior surface of the second container is arranged at a certain distance, for example 1.8 and 2.5 cm, from the interior surface of the first container. A transfer medium present either in a liquid or solid state is provided in the first container between the interior surface of the first container and the exterior surface of the second container. The transfer medium is heated by the heating element or elements also located in the first container to the vaporizing temperature required for the respective deposition medium and maintained at this constant temperature. Oil, tin or copper may preferably be used as transfer medium. Important in this respect is the fact that the temperature of the heating element or elements and of the transfer medium be adjusted in such a way that the transfer medium can not attain its vaporization temperature. A suitable transfer medium will therefore be selected in dependence of the vaporization temperature of the deposition medium. If, for example, deposition media are used whose vaporization temperature lies below 200° C., oil will preferably be used as transfer medium. If, on the other hand, deposition media are heated whose vaporization temperature lies above 200° C., a metal such as, for example, tin or copper, will be preferably used.

The deposition medium located in the second container will be heated by the heat transferred by the transfer medium to the second container to a level that allows the deposition medium to go over into its gaseous state. The internal volume of the inner container for the substance to be vaporized preferably amounts to between 0.1 liter and 5 liters. Particularly preferably, the volume will amount to between 0.5 liter and 2 liters.

Moreover, the first container as well as the second container is preferably sealed airtight by a cover. A negative pressure prevails in the second container so that the deposition medium transformed into its gaseous state can flow into the gas supply device preferably via a tube-shaped line protruding into the interior space of the second container. The fact that a negative pressure prevails in the second container moreover leads to a quicker heating of the deposition medium.

Preferably, the first container and the second container are made of a high-grade steel which allows a particularly good and efficient heat transfer from the transfer medium to the deposition medium via the wall of the second container.

Furthermore, the invention relates to a device for a gas phase deposition reaction chamber with two or more gas supply systems arranged one behind the other and/or parallel to each other. The gas supply systems may be designed and redesigned as described above. By interconnecting two or more gas supply systems, it will be possible to transform several deposition media into the gaseous phase either simultaneously or parallel in separate gas supply devices and to feed them into the reaction chamber so that multilayer coatings, i.e. coatings of several deposition media, can be deposited on the substrate. This makes it possible, for example, to deposit Cu (In, Ga) Se₂ layers (CIGS layers) on a substrate in a particularly homogeneous grid so that higher performance data may be attained. These CIGS layers are particularly suited for the manufacture of solar cells.

Dopings of the deposition medium are easily realized as well and can be applied on the substrate ad libitum. Possible dotings are, for example, portions of aluminum, zinc or tin as an admixture to the substance to be vaporized, or in an additional vaporization unit in order to bring about the inclusions of this additional substance during the deposition on the substrate. This may be advantageous, for example, for the creation of conductivity in the case of an otherwise insulating glass layer.

Alternatively, it may of course be provided that two or more deposition media are provided in a gas supply device. This lends itself in particular to a case where the vaporization temperatures and/or the vapor pressures of the employed deposition media are similar or the same.

Furthermore, the invention relates to a method for providing a gaseous deposition medium for a gas phase deposition reaction chamber in which, in particular with the use of a gas supply system designed or redesigned as described above or with the use of a device designed or redesigned as described above, a deposition medium which at room temperature is present in its liquid or solid state is transformed into its gas phase in the gas supply device and the gaseous deposition medium is transported, with the use of the gas feed device, from the gas supply device to the gas phase deposition reaction chamber and the deposition medium is fed in its gaseous state into the gas phase deposition reaction chamber.

With regard to the advantages of the method in accordance with the invention, reference is made to the full extent to the gas supply system in accordance with the invention and the device in accordance with the invention.

The method in accordance with the invention makes it advantageously possible to transform deposition media that are present in their liquid or solid states at room temperature into a gaseous state outside of preferably a CVD reaction chamber or a PECVD reaction chamber and to feed them in their heated gaseous state into the reaction chamber without the gaseous deposition medium being able to lose any heat during the transport to the reaction chamber which would lead to a disadvantageous return to the solid or liquid state of the deposition medium. Particularly at the transition between the gas supply device and the reaction chamber there will be no heat transfer from the reaction chamber to the gas supply device or vice versa due to a sealing element located there. If, for example, substrates are to be coated in the reaction chamber that are quite heat sensitive and that therefore may not (or not much) be heated during the coating process, the reaction chamber has a lower temperature than the gas supply device so that it is important that the gaseous deposition medium be prevented from losing any heat at the transition from the gas supply device to the reaction chamber due to the colder reaction chamber. Following the entry of the gaseous deposition medium in the reaction chamber, the individual atoms of the deposition medium are split off and the atoms can be deposited individually on the substrate. Therefore, no additional heat supply is required in the reaction chamber for the deposition medium.

With the method in accordance with the invention, a multitude of materials that are not present in their gas phase at room temperature can from now on be advantageously used as deposition medium or, respectively, as coating medium in the CVD or PECVD process.

In this context, the temperatures in the vaporizer are naturally adapted to the boiling or, respectively, sublimation points of the respective substances.

In this context, the feed temperature depends on vaporization of the respective deposition medium used. Here it is important that the temperature of the deposition medium be set in such a way that the deposition medium can be fed into the reaction chamber in a gaseous state.

As a rule, these values are determined empirically since the boiling and/or sublimation points of the respective materials are, as a rule, not known from the literature. This holds true particularly for conditions below normal pressure.

In accordance with another preferred embodiment, the transfer medium located in the first container of the gas supply device will be heated via the heating element located in the first container and the heat of the transfer medium is given off to the deposition medium located in the second container of the gas supply device.

In this context, the temperature of the transfer element to be set via the heating element is preferably adjusted to the vaporization temperature of the deposition medium. Depending on the vaporization temperature of the deposition medium, various transfer media may be used. Important in this context is that the transfer medium be selected in such a way that the vaporization temperature of the transfer medium is higher than the vaporization temperature of the deposition medium. If the transfer medium were vaporized, an undesired splitting of the deposition medium would result already in the gas supply device due to vibrations caused by the resulting bubbles.

Preferably, oil or a metal, preferably a low-melting metal, will be used as transfer medium. If, for example, deposition media whose vaporization temperature lies below 200° C. are heated, oil is preferably used as transfer medium. If, on the other hand, deposition media whose vaporization temperature lies above 200° C. are heated, a metal is preferably used. In this context, tin and copper are preferably used.

To this end, tin (232° C.), lead (327° C.), zinc (420° C.) are preferably used, but also copper (1,083° C.). Mainly due to environmental reasons, particular preference is given to tin and copper.

### ILLUSTRATIONS AND EXAMPLES

In the following, the invention will be explained in detail by way of a preferred embodiment with references to the attached drawings.

Shown are:

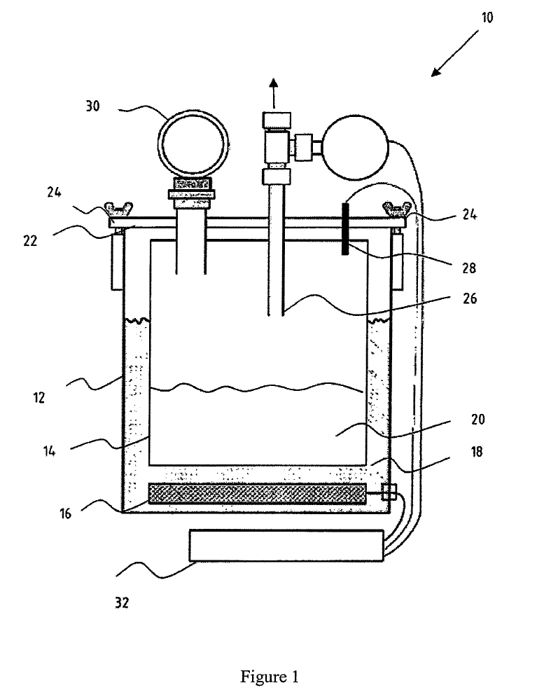

in FIG. 1 a schematic representation of a sectional view of a gas supply device in accordance with the invention,

in FIG. 2 a schematic representation of a sectional view of a valve in accordance with the invention,

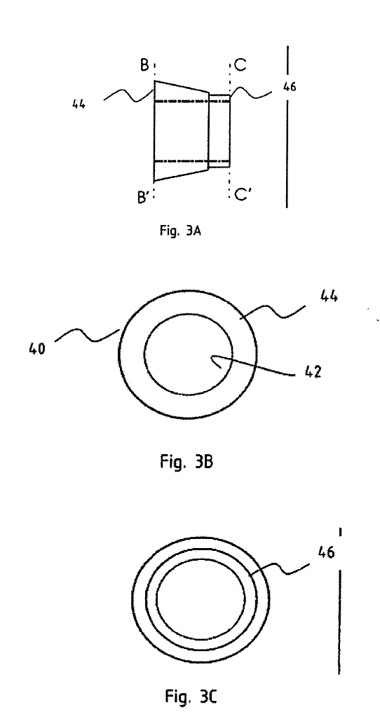

in FIG. 3A a schematic representation of a lateral sectional view of a sealing element in accordance with the invention,

in FIG. 3B a schematic representation of a sectional view of the sealing element in accordance with the invention in a cut along the cut line B-B drawn in in FIG. 3A (frontal view)

in FIG. 3C a schematic representation of the sealing element in accordance with the invention in a cut along the cut line C-A drawn in in FIG. 3A (rear view)

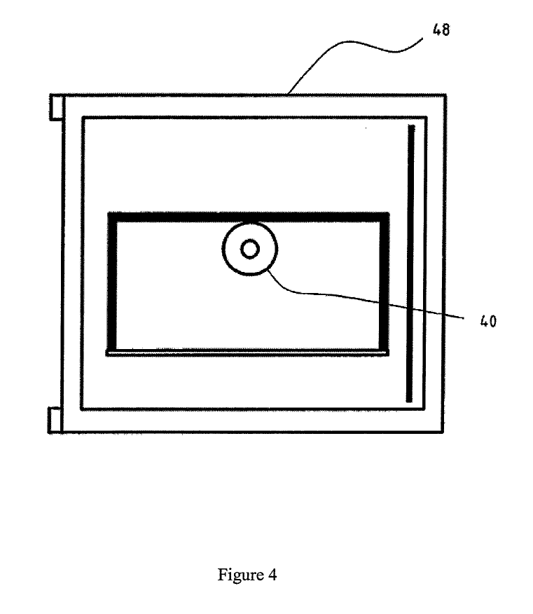

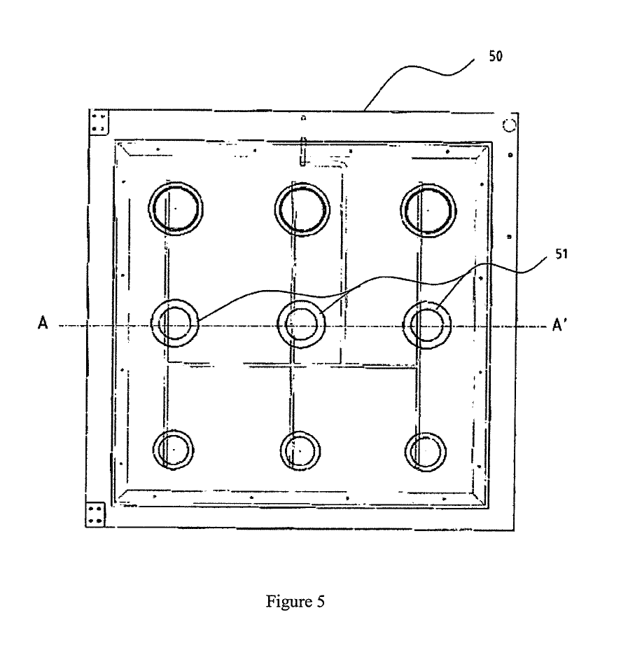

in FIGS. 4 and 5 a schematic representation each of a gas phase deposition reaction chamber, as well as

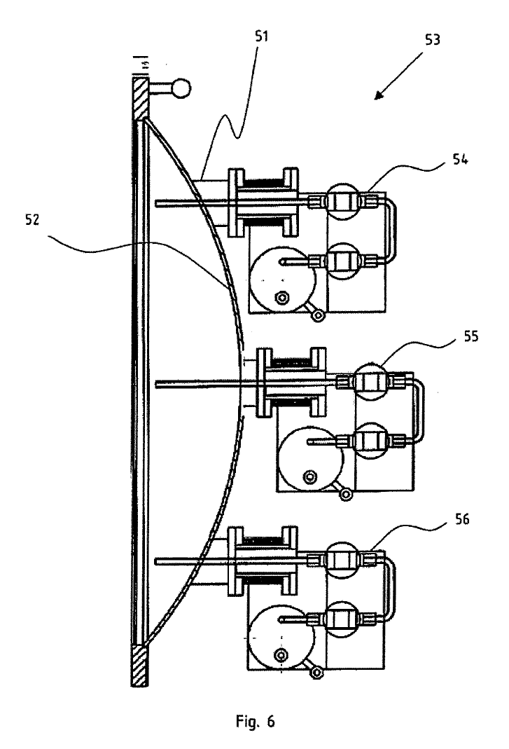

in FIG. 6 a cross sectional view through the door of a gas phase deposition reaction chamber with gas supply devices in accordance with the invention attached thereto.

In FIG. 1, a gas supply device 10 is shown which has a first container 12 and a second container 14 arranged in the first container 12. A heating element 16 and a transfer medium 18 are arranged in the first container 12. To this end, for example oil or a metal, such as, for example, tin or copper, may be used as transfer medium 18. The second container 14 contains a deposition medium 20 which is present in liquid or solid form at room temperature. Preferably, the container 14 will always contain only one deposition medium in order to avoid any undesired mutual influencing of different deposition media. The first container 12 as well as the second container 14 are sealed airtight by means of a lid 22 that can be fixed in its position for example by means of screws 24. Furthermore, a tube-shaped line 26 for the transport of the heated deposition medium 20 transformed into its gaseous state to the gas feed device; a temperature sensor 28 as well as a pressure gauge 30 are provided in the second container 14.

The transfer medium 18 is heated to a temperature adjusted to the vaporization temperature of the deposition medium 20 with the aid of the heating element 16. In this step, the transfer medium 18 should reach a temperature that lies above the vaporization temperature of the deposition medium 20. The heat of the heated transfer medium 18 is transferred to the deposition medium 20 via the container wall of the second container 14; the deposition medium is heated at least to its vaporization temperature and is thereby transformed into its gaseous state. The heated gaseous deposition medium 20 leaves the second container 14 via a tube-shaped line 26 and enters the gas feed device.

In order to make an optimal temperature setting possible in the first container 12 and in the second container 14, the heating element 16 as well as the temperature sensor 28 is connected to a control unit 32.

After leaving the second container 14 via the tube-shaped line 26, the heated gaseous deposition medium 20 preferably flows into a valve 34 like the one shown in FIG. 2 which is located within the gas feed device. The valve 34 is preferably designed as a needle valve. To prevent the gaseous deposition medium 20 from cooling down within the valve 34, a heating element 36 as well as a temperature sensor 38 is provided within the valve 34 for an optimal temperature setting of the heating element 36. The feed of the desired volume flow of the gaseous deposition medium 20 into the reaction chamber is optimally controlled with the aid of the valve 34.

Starting from the valve 34, the heated gaseous deposition medium 20 is transported to the reaction chamber 48 shown in FIG. 4 via a preferably tube-shaped line. To prevent the deposition medium 20 from cooling down at the transition from the gas feed device to the reaction chamber 48, a sealing element 40 for a thermal and airtight seal is preferably arranged on the exterior circumferential surface of the tube-shaped line.

The sealing element 40 is preferably a PTFE ring as shown in FIGS. 3A, 3B and 3C that can be easily pulled onto the tube-shaped line with its interior surface 42. The frontal exterior surface 44 of the PTFE ring is preferably designed in the form of a trapeze. The rear exterior surface 46 of the PTFE ring that can be inserted at least partially into the opening of the reaction chamber moreover preferably has a cylindrical shape. The PTFE ring 40 can thus be attached in force-fitting form in the entry opening of the reaction chamber between the tube-shaped line and the wall of the reaction chamber.

Moreover, FIG. 4 shows a gas phase deposition reaction chamber 48, preferably a PECVD chamber, in which a PTFE ring 40 is arranged in the entry opening in the reaction chamber 48.

FIG. 5 also shows a gas phase deposition reaction chamber 50, preferably a PECVD chamber, in a frontal view; in the embodiment 9 shown, it is equipped with sealable entry openings to which the various feed devices can be attached.

The three feed devices 51 located centrally in a vertical direction are preferably used for the attachment of one or several gas supply systems in accordance with the invention.

FIG. 6 shows a top view of a cut along the line A-A′ in FIG. 5. Shown is the door 52 of a gas phase deposition reaction chamber 53 with the three centrally arranged feed devices 51 as well as three gas supply devices 54-56 in accordance with the invention attached thereto. The gas supply devices are each equipped with a needle valve—not shown—as well as with a tube protruding into the gas phase deposition reaction chamber.

Said needle valve is designed to be heat resistant so that it will survive temperatures of up to 600° C., in contrast with a MFC that will not survive such a temperature.

This may be advantageous in the case of deposition media that need to be heated to very high temperatures in the gas supply system in accordance with the invention in order to transition into the gas phase.

Due to the heat resistance of the needle valve, such media can pass through the valve at the aforementioned temperature and will cool down only downstream of the valve, i.e. in the reaction chamber where preferably a high vacuum prevails and condensation is no longer to be feared.

The various gas supply devices running parallel are required in particular when a coating is to occur with several deposition media that are solid or liquid at room temperature, for example one after the other or simultaneously. This may be required in particular in the manufacture of solar cells.

### EXAMPLE

650 g of titanium isopropoxide (Ti [OCH(CH₃)₂]₄) are placed into a gas supply system as described above which has an interior volume of 2,000 ml. The gas supply system is connected via a gas feed device in accordance with the invention to a PECVD chamber (model designation) into which a flat work piece (60×60 cm, 5 mm thickness) made of hardened glass has been placed. The PECVD chamber is evacuated to a residual pressure of measured 0.1 Pa. Since the valve arranged in the area of the gas supply device is closed, pressure conditions are created in the gas supply system that are independent of the plasma chamber.

The interior container of the gas supply system is heated with the aid of an oil bath. Under the given pressure conditions, the deposition medium transitions into the gas phase starting at a temperature of 140° C.

The transition can be read on the pressure gauge since the pressure increases with vaporization, i.e. with an increased gas portion in the closed container, relative to the initial pressure following the filling of the vaporizer. During the later course, at least this temperature will be maintained in the vaporizer. Also, a negative pressure will be created when the valve is opened later, creating an atmospheric balance. It lowers the boiling point of the coating material further, thereby assuring a permanent supply of the latter in its gaseous state.

In the meantime, an inert protective gas is fed into the plasma chamber. Argon (Ar) is used at a gas flow rate of 70 sccm. Another gas is fed in addition thereto which is needed for the desired type of deposition of titanium. If one wishes to create a metallic layer, hydrogen gas (H2) will be added. In this context, its gas flow rate should correspond to the flow of the coating material, in this example 100 sccm. A plasma is subsequently ignited in the chamber by applying an HF field (bias voltage: 250 V, frequency: 13.7 MHz).

Subsequently, the valve of the gas supply device is opened enough so that a gas flow of 100 sccm can be maintained. The gas will now flow into the plasma chamber through the heat continuum of the gas supply device and the gas feed device.

Due to the effects of the plasma, the components of the gaseous coating material are ionized and the chemical bonding of the titanium isopropoxide is split. While other components of the compound react with hydrogen ions and are suctioned off in neutral form, the titanium ions are positively charged and accelerated onto the substrate circuited as a cathode, i.e. negatively. In this process, titanium ions impact on the surface of the work piece to be coated where they are neutralized by the electrons, thereby firmly attaching themselves on the substrate surface.

In this manner, a metallic titanium layer will be obtained having a layer thickness of 2 μm after a coating period of 30 minutes.

1-2. (canceled)

21. A gas supply system for a gas phase deposition reaction chamber with a gas supply device, wherein the gas supply device has at least one heating element for the heating of a deposition medium that is solid or liquid at room temperature and for the transformation of the deposition medium into the gas phase, as well as with a gas feed device for the transport of the deposition medium transformed into the gas phase from the gas supply device into the gas phase deposition reaction chamber.

22. The gas supply system of claim 21, wherein the gas phase deposition reaction chamber comprises a PECVD chamber.

23. The gas supply system of claim 21, wherein the gas feed device is equipped with a sealing element at the transition to the gas phase deposition reaction chamber.

24. The gas supply system of claim 23, wherein the sealing element is connected in force-fitting form at the transition section between the gas feed device and the reaction chamber above the exterior circumferential surface of the gas feed device, and/or is arranged in the area of the opening of the reaction chamber through which the gas feed device runs into the interior space of the reaction chamber in such a way that it will bring about a pneumatic and thermal seal between the exterior circumferential surface of the gas feed device and the wall of the reaction chamber.

25. The gas supply system of claim 21, wherein the gas supply device and the gas feed device are designed as a continuously tempered and/or thermally insulated continuum.

26. The gas supply system of claim 21, wherein a valve to control the feed of the gaseous deposition medium is provided between the gas supply device and the gas phase deposition reaction chamber.

27. The gas supply system of claim 26, wherein the valve involves a needle valve.

28. The gas supply system of claim 21, wherein a valve is positioned between the gas supply device and the gas phase deposition reaction chamber to control the pressure conditions between the two devices.

29. The gas supply system of claim 23, wherein the sealing element is a PTFE element.

30. The gas supply system of claim 21, wherein the gas supply device is equipped with a first container and a second container located in the first container, with the heating element and a transfer medium for the transfer of the heat emitted by the heating element to the second container being provided in the first container and the deposition medium being provided in the second container.

31. The gas supply system of claim 30, wherein the first container and the second container are made of stainless steel.

32. A device for a gas phase deposition reaction chamber with two or more gas supply systems arranged in series and/or parallel to each other in accordance with claim 1.

33. The device of claim 32, wherein the gas phase deposition reaction chamber comprises a PECVD gas phase deposition reaction chamber.

34. A method for providing a gaseous deposition medium for a gas phase deposition reaction chamber, in which a deposition medium present in its liquid or solid state at room temperature is transformed into the gas phase by means of applying heat, using the gas supply system of claim 1, with the gaseous deposition medium being transported from the gas supply device to the gas phase deposition reaction chamber with the aid of the gas feed device and the deposition medium being fed into the gas phase deposition reaction chamber in its gaseous state.

35. The method of claim 34, wherein the deposition medium is fed into the gas phase deposition reaction chamber in its gaseous state at a temperature of greater than 100° C.

36. The method of claim 34, wherein the deposition medium is transformed into the gas phase in the gas supply device under negative pressure.

37. The method of claim 34, wherein a valve is used to feed the gaseous deposition medium into the gas phase deposition reaction chamber.

38. The method of claim 34, wherein the transfer medium arranged in the first container of the gas supply device is heated via the heating element arranged in the first container and the heat of the transfer medium is transferred to the deposition medium arranged in the second container.

39. The method of claim 34, wherein the temperature of the transfer medium to be set via the heating element is adjusted to the vaporization temperature of the deposition medium.

40. The method of claim 34, wherein oil or a metal is used as transfer medium.
